(19) United States
(12) Patent Application Publication
(10) Pub. No.: US 2014/0151328 A1
(43) Pub. Date: Jun. 5, 2014

(54) METHOD FOR FORMING LAMINATE

(71) Applicant: Tokyo Ohka Kogyo Co., Ltd., Kawasaki-shi (JP)

(72) Inventors: Atsushi Miyanari, Kawasaki-shi (JP); Akihiko Nakamura, Kawasaki-shi (JP)

(73) Assignee: Tokyo Ohka Kogyo Co., Ltd., Kawasaki-shi (JP)

(21) Appl. No.: 14/072,158

(22) Filed: Nov. 5, 2013

(30) Foreign Application Priority Data
Dec. 5, 2012 (JP) 2012-266699

(51) Int. Cl. H01L 21/683

(52) U.S. Cl. CPC H01L 21/6836
USPC 216/33; 156/247; 156/285

(57) ABSTRACT

A release layer is adequately protected by a protective layer when a laminate is subjected to a desired treatment. A method for forming a laminate 10 includes a protective layer forming step of forming a protective layer 15 for covering a face that is a surface of a release layer 14 and which is not adhered to a support plate 12 and not superimposed at least on an adhesive layer 13; and a protective layer removal step of removing a portion of the protective layer 15, which is exposed at the time of forming the laminate 10.

### CROSS-REFERENCE TO RELATED APPLICATIONS

Priority is claimed on Japanese Patent Application No. 2012-266699, filed Dec. 5, 2012, the content of which is incorporated herein by reference.

### TECHNICAL FIELD

The present invention relates to a method for forming a laminate.

### BACKGROUND ART

In recent years, thinning, downsizing, weight reduction, and the like of electronic appliances such as IC cards and mobile phones are required. In order to meet these requirements, a thinned semiconductor chip must be used even for semiconductor chips which are installed. For that reason, although a thickness (film thickness) of a wafer substrate which is a basis of the semiconductor chip is 125 μm to 150 lam in the existing circumstances, it is said that the thickness must be reduced to an extent of 25 μm to 50 μm for chips of the next generation. In consequence, in order to obtain a wafer substrate having the above-described film thickness, a thinning step of the wafer substrate is necessary and indispensable.

In the wafer substrate, its strength is lowered by thinning. Therefore, in order to prevent damage of the thinned wafer substrate from occurring, structures such as a circuit are mounted on the wafer substrate while automatically conveying the wafer substrate in a state of sticking a support plate thereto during a manufacturing process. Then, after the manufacturing process, the wafer substrate is separated from the support plate. In consequence, though during the manufacturing process, it is preferable that the wafer substrate and the support plate are firmly adhered to each other, after the manufacturing process, it is preferable that the wafer substrate can be smoothly separated from the support plate.

In the case of firmly adhering the wafer substrate and the support plate to each other, it is difficult to separate the support plate from the wafer substrate without damaging the structures mounted on the wafer substrate depending upon an adhesive material. In consequence, the development of a very difficult temporary adhesion technology for realizing firm adhesion between the wafer substrate and the support plate during the manufacturing process and meanwhile separating an element mounted on the wafer substrate without being damaged after the manufacturing process is demanded.

At the time of partially removing an adhesive in the vicinity of the outer periphery of a wafer by using a solvent such that it is thinner than the adhesive in the inside and then sticking the wafer and a holding plate to each other, as a method for applying the adhesive to the wafer so as to make the quantity of polishing of the both equal to each other, a method described in Patent Literature 1 is known.

In addition, as a method for manufacturing a semiconductor chip by sticking a support to a semiconductor wafer, treating the semiconductor wafer, and then separating the support, a method described in Patent Literature 2 is known. In the method described in Patent Literature 2, a light-transmitting support and a semiconductor wafer are stuck to each other via a photothermal conversion layer and an adhesive layer provided on the support side; the semiconductor wafer is treated; radiation energy is radiated from the support side to decompose the photothermal conversion layer; and the semiconductor wafer is separated from the support.

### CITATION LIST

### Patent Literatures

Patent Literature 1
Japanese Patent Application Publication, Tokukai, No. 2001-189292 (Publication Date: Jul. 10, 2001)
Patent Literature 2
Japanese Patent Application Publication, Tokukai, No. 2005-159155 (Publication Date: Jun. 16, 2005)

### SUMMARY OF THE INVENTION

### Technical Problem

However, when various treatments are conducted on a laminate in which a wafer and a support are stuck to each other via a photothermal conversion layer (release layer), there is a concern that the photothermal conversion layer is denatured with a chemical and the like on the way of the treatment, so that the wafer is peeled off.

For example, in a resist stripping step or the like, in particular, when the laminate is exposed to a stripper at a high temperature, the stripper penetrates from an edge end face of the laminate, so that the wafer is peeled off.

When the wafer i3 peeled off on the way of the treatment, the wafer is cracked or broken or generates irregularities, and therefore, it may be impossible to make the step advance to a next step.

In view of these circumstances, the method for forming a laminate according to the present invention has been made, and an object thereof is to adequately protect a release layer by a protective layer when conducting a desired treatment on the laminate.

### Solution to Problem

In order to solve the foregoing problem, the method for forming a laminate according to the present invention is concerned with a method for forming a laminate comprising laminating a substrate, an adhesive layer, a release layer which is denatured upon absorption of light, and a support supporting the substrate in this order to form a laminate, the method including a protective layer forming step of forming a protective layer for covering a face that is a surface of the release layer and which is not adhered to the support and not superimposed at least on the adhesive layer; and a protective layer removal step of removing a portion of the protective layer, which is exposed at the time of forming the laminate.

In addition, the method for forming a laminate according to the present invention is concerned with a method for forming a laminate comprising laminating a substrate, an adhesive layer, a release layer which is denatured upon absorption of light, and a support supporting the substrate in this order to form a laminate, the method including a release layer removal step of removing a portion of the release layer, which is exposed at the time of forming the laminate, by a plasma treatment.

### Advantageous Effects of Invention

When the laminate is subjected to a desired treatment, the method for forming a laminate according to the present invention gives rise to an effect for one to adequately protect the release layer by the protective layer.

### BRIEF DESCRIPTION OF DRAWINGS

FIGS. 1(a) to 1(f) are each a view illustrating a method for forming a laminate in the case of removing a portion of a protective layer, which is exposed at the time of forming the laminate, before an adhesion step.

FIGS. 2(a) to 2(f) are each a view illustrating a method for forming a laminate in the case of removing a portion of a protective layer, which is exposed at the time of forming the laminate, after an adhesion step.

FIGS. 3(a) to 3(f) are each a view illustrating a method for forming a laminate in the case of not removing an exposed protective layer.

### DETAILED DESCRIPTION OF THE PREFERRED EMBODIMENTS

### Method for Forming Laminate (Reference)

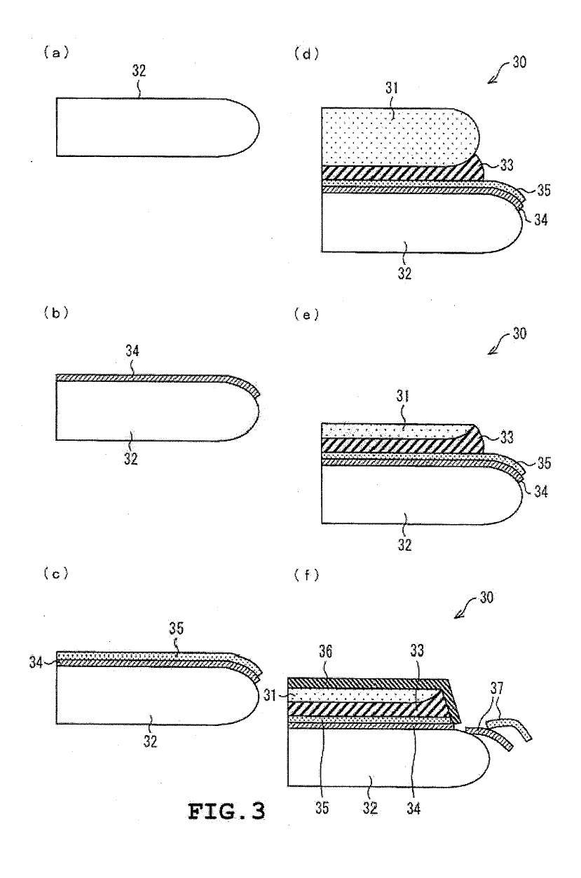

First of all, for reference, a method for forming a laminate 30 is described by reference to FIGS. 3(a) to 3(f). FIGS. 3(a) to 3(f) are each a view illustrating a method for forming a laminate in the case of not removing an exposed protective layer.

First of all, as illustrated in FIGS. 3(a) and 3(b), a release layer 34 is formed on a support plate 32.

Subsequently, as illustrated in FIG. 3(c), a protective layer 35 is formed on the release layer 34. In the case of forming the protective layer 35, the protective layer 35 is formed so as to cover a face that is a surface of the release layer 34 and which is not superimposed on the support plate 32.

As illustrated in FIG. 3(d), an adhesive layer 33 is formed on at least either one of the protective layer 35 and a substrate 31, and the protective layer 35 and the substrate 31 are stuck to each other via the adhesive layer 33, thereby manufacturing the laminate 30.

As illustrated in FIG. 3(e), a face of the substrate 31 opposite to the side on which the adhesive layer 33 is formed is ground and thinned.

After grinding and thinning the substrate 31, the substrate 31 is subjected to at least one of a heat treatment and a vacuum treatment. According to this, as illustrated in FIG. 3(f), not only a CVD film 36 is formed on the substrate 31, but the CVD film 36 and the exposed protective layer 35 come into contact with each other. According to this, the release layer 34 and the protective layer 35 (particularly the protective layer 35), which have been formed on a curved surface of the support plate 32, are peeled off, whereby a peeled material 37 is generated. In the view of the fact that the release layer 34 and the protective layer 35 are peeled off, there is a concern that particles and the like are generated to deposit on the substrate 31, thereby staining the substrate 31.

Therefore, when the laminate is subjected to a desired treatment such as a heat treatment and a vacuum treatment, it is necessary to adequately protect the laminate such that the protective layer and the release layer are not peeled from the support. It is to be noted that each of the constitutions forming the laminate (for example, the protective layer, the release layer, etc.) is described in detail in the following embodiments.

### EMBODIMENTS

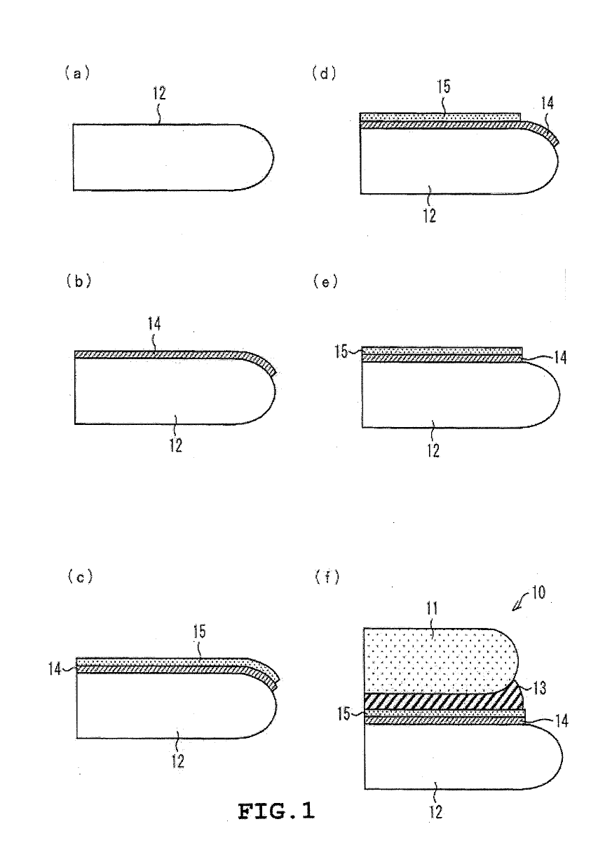

An embodiment of the present invention is hereunder described in detail. According to the present embodiment, a laminate 10 is formed as illustrated in FIG. 1(f).

A method for forming a laminate 10 according to the present embodiment is concerned with a method for forming a laminate 10 comprising laminating a substrate 11, an adhesive layer 13, a release layer 14 which is denatured upon absorption of light, and a support plate (support) 12 supporting the substrate 11 in this order to form the laminate 10, the method including a protective layer forming step of forming a protective layer 15 for covering a face that is a surface of the release layer 14 and which is not adhered to the support plate 12 and not superimposed at least on the adhesive layer 13; and a protective layer removal step of removing a portion of the protective layer 15, which is exposed at the time of forming the laminate 10. First of all, each of the constitutions forming the laminate 10 is hereunder described in detail.

[Substrate]

The substrate 11 is provided for processes such as thinning and mounting in a state where the substrate 11 is supported by the support plate 12. The substrate 11 which is included in the laminate 10 is not limited to a wafer, and an arbitrary substrate such as a thin film substrate and a flexible substrate can be adopted. In addition, a fine structure of an electronic element, such as an electric circuit, may be formed on a face of the substrate 11 on the side of the adhesive layer 13.

[Support Plate]

The support plate 12 is a support supporting the substrate 11 and has light transmission properties. For that reason, when light is radiated from the outside of the laminate 10 toward the support plate 12, the light concerned passes through the support plate 12 and reaches the release layer 14. In addition, the support plate 12 is not always necessary to transmit all of the light therethrough, and is only necessary to be able to transmit the light to be absorbed in the release layer 14 (having a prescribed wavelength) therethrough.

The support plate 12 is one supporting the substrate 11, and it may have strength necessary for preventing damage or deformation of the substrate 11 from occurring at the time of processes such as thinning, conveyance, and mounting of the substrate 11. From such viewpoints, examples of the support plate 12 include those made of glass, silicon, or an acrylic resin.

[Release Layer]

The release layer 14 is a layer formed of a material which is denatured upon absorption of the light which is irradiated via the support plate 12. In this specification, what the release layer 14 is “denatured” means a phenomenon for realizing a state where the release layer 14 may be broken upon receiving a slight external force, or a state where an adhesive strength to a layer coming into contact with the release layer 14 is lowered. As a result of denaturation of the release layer 14 which is caused upon absorption of light, the release layer 14 loses the strength or adhesiveness before receiving the irradiation with light. Therefore, by applying a slight external force (for example, lifting up the support plate 12, etc.), the release layer 14 is broken, thereby making it possible to separate the support plate 12 and the substrate 11 from each other with ease.

In addition, the denaturation of the release layer 14 may be (pyrogenic or non-pyrogenic) decomposition, crosslinking, change of configuration, or dissociation of a functional group (and curing, degasification, shrinkage, or expansion of the release layer 14 accompanying therewith) by energy of absorbed light, or the like. The denaturation of the release layer 14 is generated as a result of the absorption of light by the material constituting the release layer 14. Therefore, a type of denaturation of the release layer 14 is variable depending upon a kind of the material constituting the release layer 14.

The release layer 14 is provided on a surface of the support plate 12 on the side to which the substrate 11 is stuck via the adhesive layer 13. That is, the release layer 14 is provided between the support plate 12 and the adhesive layer 13.

A thickness of the release layer 14 is, for example, more preferably 0.05 μm to 50 μm, and still more preferably 0.3 μm to 1 μm. So far as the thickness of the release layer 14 falls within the range of 0.05 μm to 50 μm, desired denaturation can be generated in the release layer 14 upon irradiation with light for a short time and irradiation with light having low energy. In addition, from the viewpoint of productivity, it is especially preferable that the thickness of the release layer 14 falls within the range of not more than 1 μm.

It is to be noted that in the laminate 10, other layer may be further formed between the release layer 14 and the support plate 12. In that case, the other layer is only necessary to be constituted of a material capable of transmitting light therethrough. According to this, a layer capable of imparting preferred properties to the laminate 10 without disturbing incidence of light into the release layer 14 can be properly added. A wavelength of the light which may be used varies depending upon a kind of the material constituting the release layer 14. Therefore, the material constituting the other layer is not necessary to transmit all of the light therethrough, and it may be properly selected among materials capable of transmitting light having a wavelength capable of denaturing the material constituting the release layer 14 therethrough.

In addition, it is preferable that the release layer 14 is formed of only a material having a structure capable of absorbing light. However, the release layer 14 may also be formed by the addition of a material not having a structure capable of absorbing light within a range where the essential properties are not impaired. In addition, it is preferable that a face of the release layer 14 on the side opposing to the adhesive layer 13 is flat (irregularities are not formed). According to this, not only the formation of the release layer 14 can be easily achieved, but even at the time of sticking, it is possible to achieve uniform sticking.

As for the release layer 14, a layer prepared by previously forming a material constituting the release layer 14 in a film shape as described below and sticking it to the support plate 12 may be used, or a layer prepared by applying a material constituting the release layer 14 onto the support plate 12 and solidifying it in a film shape may be used. A method for applying a material constituting the release layer 14 onto the support plate 12 can be properly selected among conventionally known methods such as accumulation by a chemical vapor deposition (CVD) method depending upon a kind of the material constituting the release layer 14.

The release layer 14 may also be a layer which is denatured upon absorption of light which is radiated from a laser. That is, the light which is radiated on the release layer 14 for the purpose of denaturing the release layer 14 may be light radiated from a laser. Examples of the light which is radiated on the release layer 14 include solid lasers such as a YAG laser, a ruby laser, a glass laser, a YVO₄ laser, an LD laser, and a fiber laser; liquid lasers such as a dye laser; gas lasers such as a CO₂ laser, an excimer laser, an Ar laser, and a He—Ne laser; laser lights such as a semiconductor laser and a free electron laser; and non-laser lights. It is possible to properly select the laser capable of emitting light which is radiated on the release layer 14 depending upon the material constituting the release layer 14, and it is only necessary that a laser radiating light having a wavelength capable of denaturing the material constituting the release layer 14 may be selected.

(Polymer Containing a Structure Having Light Absorption Properties in its Repeating Unit)

The release layer 14 may contain a polymer containing a structure having light absorption properties in its repeating unit. The polymer concerned is denatured upon receipt of irradiation with light. The denaturation of the polymer concerned is generated due to the fact that the above-described structure absorbs the radiated light. As a result of the denaturation of the polymer, the release layer 14 loses the strength or adhesiveness before receiving the irradiation with light. Therefore, by applying a slight external force (for example, lifting up the support plate 12, etc.), the release layer 14 is broken, thereby making it possible to separate the support plate 12 and the substrate 11 from each other with ease.

The above-described structure having light absorption properties is a chemical structure in which the polymer containing the structure concerned as a repeating unit is denatured upon absorption of light. The structure concerned is, for example, an atomic group containing a conjugated π-electron system composed of a substituted or unsubstituted benzene ring, condensed ring or heterocyclic ring. In more detail, the structure concerned may be a cardo structure; or a benzophenone structure, a diphenylsulfoxide structure, a diphenylsulfone structure (bisphenylsulfone structure), a diphenyl structure, or a diphenylamine structure, each existing in a side chain of the above-described polymer.

In the case where the above-described structure exists in a side chain of the above-described polymer, the structure concerned may be represented by any of the following formulae.

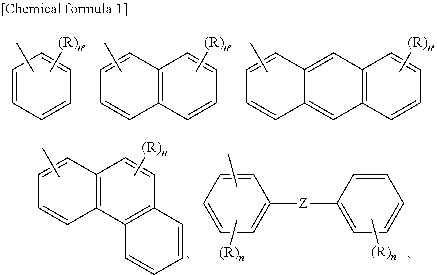

In the foregoing formulae, each R is independently an alkyl group, an aryl group, a halogen, a hydroxyl group, a ketone group, a sulfoxide group, a sulfone group, or N(R₁) (R₂) (here, each of R₁ and R₂ is independently a hydrogen atom or an alkyl group having 1 to 5 carbon atoms); Z does not exist or is —CO—, —SO₂—, —SO—, or —NH—; and n is 0 or an integer of 1 to 5.

In addition, for example, the above-described polymer contains a repeating unit represented by any one of the following structures (a) to (d), is represented by the following structure (e), or contains the following structure (f) in a main chain thereof.

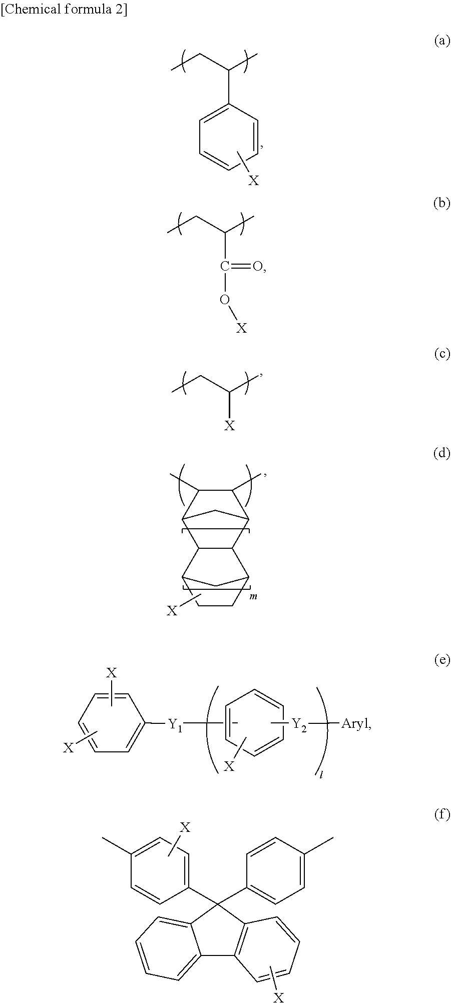

In the foregoing formulae, l is an integer of 1 or more; m is 0 or an integer of 1 to 2; X is any one of the formulae shown in the above-described “Chemical formula I” in (a) to (e), or X is any one of the formulae shown in the above-described “Chemical formula I” in (f) or does not exist; and each of Y₁ and Y₂ is independently —CO— or —SO₂—. l is preferably an integer of not more than 10.

Examples of the benzene ring, the condensed ring, and the heterocyclic ring shown in the above-described “Chemical formula I” include phenyl, substituted phenyl, benzyl, substituted benzyl, naphthalene, substituted naphthalene, anthracene, substituted anthracene, anthraquinone, substituted anthraquinone, acridine, substituted acridine, azobenzene, substituted azobenzene, fluorene, substituted fluorene, fluorenone, substituted fluorenone, carbazole, substituted carbazole, N-alkylcarbazole, dibenzofuran, substituted dibenzofuran, phenanthrene, substituted phenanthrene, pyrene, and substituted pyrene. In the case where each of the above-exemplified substituents has a substituent, the substituent is, for example, selected among alkyl, aryl, halogen atom, alkoxy, nitro, aldehyde, cyano, amide, dialkylamino, sulfonamide, imide, carboxylic acid, carboxylic acid ester, sulfonic acid, sulfonic acid ester, alkylamino, and arylamino.

Among the substituents shown in the above-described “Chemical formula I”, examples of the fifth substituent having two phenyl groups and containing —SO₂— as Z include bis(2,4-dihydroxyphenyl)sulfone, bis(3,4-dihydroxyphenyl)sulfone, bis(3,5-dihydroxyphenyl)sulfone, bis(3,6-dihydroxyphenyl)sulfone, bis(4-hydroxyphenyl)sulfone, bis(3-hydroxyphenyl)sulfone, bis(2-hydroxyphenyl)sulfone, and bis(3,5-dimethyl-4-hydroxyphenyl)sulfone.

Among the substituents shown in the above-described “Chemical formula 1”, examples of the fifth substituent having two phenyl groups and containing —SO— as Z include bis(2,3-dihydroxyphenyl)sulfoxide, bis(5-chloro-2,3-dihydroxyphenyl)sulfoxide, bis(2,4-dihydroxyphenyl)sulfoxide, bis(2,4-dihydroxy-6-methylphenyl)sulfoxide, bis(5-chloro-2,4-dihydroxyphenyl)sulfoxide, bis(2,5-dihydroxyphenyl)sulfoxide, bis(3,4-dihydroxyphenyl)sulfoxide, bis(3,5-dihydroxyphenyl)sulfoxide, bis(2,3,4-trihydroxyphenyl)sulfoxide, bis(2,3,4-trihydroxy-6-methylphenyl)sulfoxide, bis(5-chloro-2,3,4-trihydroxyphenyl)sulfoxide, bis(2,4,6-trihydroxyphenyl)sulfoxide, and bis(5-chloro-2,4,6-trihydroxyphenyl)sulfoxide.

Among the substituents shown in the above-described “Chemical formula 1”, examples of the fifth substituent having two phenyl groups and containing —C(═O)— as Z include 2,4-dihydroxybenzophenone, 2,3,4-trihydroxybenzophenone, 2,2′,4,4′-tetrahydroxybenzophenone, 2,2′,5,6′-tetrahydroxybenzophenone, 2-hydroxy-4-methoxybenzophenone, 2-hydroxy-4-octoxybenzophenone, 2-hydroxy-4-dodecyloxybenzophenone, 2,2′-dihydroxy-4-methoxybenzophenone, 2,6-dihydroxy-4-methoxybenzophenone, 2,2′-dihydroxy-4,4′-dimethoxybenzophenone, 4-amino-2′-hydroxybenzophenone, 4-dimethylamino-2′-hydroxybenzophenone, 4-diethylamino-2′-hydroxybenzophenone, 4-dimethylamino-4′-methoxy-2′-hydroxybenzophenone, 4-dimethylamino-2′,4′-dihydroxybenzophenone, and 4-dimethylamino-3′,4′-dihydroxybenzophenone.

In the case where the above-described structure exists in a side chain of the above-described polymer, a proportion of the repeating unit containing the above-described structure occupying in the above-described polymer falls within a range where a light transmittance of the release layer 14 is 0.001% to 10%. So far as the polymer is prepared such that the proportion concerned falls within the foregoing range, the release layer 14 may be denatured surely and rapidly by thoroughly absorbing light. That is, the removal of the support plate 12 from the laminate 10 is easy, so that an irradiation time of light necessary for the removal can be shortened.

The above-described structure is able to absorb light having a wavelength of a desired range through selection of its kind. For example, the wavelength of the light which can be absorbed by the above-described structure is more preferably 100 nm to 2,000 nm. In the foregoing range, the wavelength of light which can be absorbed by the above-described structure is located on the side of a shorter wavelength, and it is, for example, 100 nm to 500 nm. For example, the above-described structure may denature a polymer having the structure concerned by absorbing an ultraviolet light having a wavelength of preferably about 300 nm to 370 nm.

The light which can be absorbed by the above-described structure is, for example, light emitted from a high pressure mercury vapor lamp (wavelength: 254 nm to 436 nm), a KrF excimer laser (wavelength: 248 nm), an ArF excimer laser (wavelength: 193 nm), an F_{z} excimer laser (wavelength: 157 nm), an XeCl laser (wavelength: 308 nm), an XeF laser (wavelength: 351 nm), or a solid UV laser (wavelength: 355 nm); or a g-line (wavelength: 436 nm), an h-line (wavelength: 405 nm), or an i-line (wavelength: 365 nm).

Though the above-described release layer 14 contains a polymer containing the above-described structure as a repeating unit, the release layer 14 may further contain other component than the above-described polymer. Examples of the component concerned include a filler, a plasticizer, and a component capable of enhancing separation properties of the support plate 12. Such a component is properly selected among conventionally known substances or materials that do not hinder the absorption of light by the above-described structure and the denaturation of the polymer, or promote them.

(Inorganic Material)

The release layer 14 may also be made of an organic material. In view of the fact that the release layer 14 is constituted of an inorganic material, the release layer 14 is denatured upon absorption of light. As a result, the release layer 14 loses the strength or adhesiveness before receiving the irradiation with light. Therefore, by applying a slight external force (for example, lifting up the support plate 12, etc.), the release layer 14 is broken, thereby making it possible to separate the support plate 12 and the substrate 11 from each other with ease.

The inorganic material is only necessary to have a constitution which is denatured upon absorption of light, and for example, one or more kinds of inorganic materials selected from the group consisting of a metal, a metal compound, and carbon can be suitably used. The metal compound refers to a compound containing a metal atom and may be, for example, a metal oxide or a metal nitride. Though such an inorganic material is not limited thereto, examples thereof include one or more kinds of inorganic materials selected from the group consisting of gold, silver, copper, iron, nickel, aluminum, titanium, chromium, SiO₂, SiN, Si₃N₄, TiN, and carbon. It is to be noted that the term “carbon” is a concept inclusive of an allotrope of carbon, and for example, it may be diamond, fullerene, diamond-like carbon, or carbon nanotube.

The inorganic material absorbs light having a wavelength of an inherent range depending upon its kind. By irradiating the release layer 14 with light having a wavelength of a range where the inorganic material used in the release layer 14 absorbs, the inorganic material may be suitably denatured.

The light which is radiated on the release layer 14 made of an inorganic material may be properly used among solid lasers such as a YAG laser, a ruby laser, a glass laser, a YVO₄ laser, an LD laser, and a fiber laser; liquid lasers such as a dye laser; gas lasers such as a CO₂ laser, an excimer laser, an Ar laser, and a He—Ne laser; laser lights such as a semiconductor laser and a free electron laser; and non-laser lights, depending upon the wavelength which can be absorbed by the inorganic material.

The release layer 14 made of an inorganic material may be formed on the support plate 12 by a known technology, for example, sputtering, chemical vapor deposition (CVD), plating, plasma CVD, spin application, etc. A thickness of the release layer 14 made of an inorganic material is not particularly limited, and it only needs to be a film thickness at which the light used may be thoroughly absorbed. The thickness of the release layer 14 made of an inorganic material is, for example, more preferably 0.05 μm to 10 μm. In addition, an adhesive may be previously applied onto both surfaces or one surface of an inorganic film (for example, a metal film) made of an inorganic material constituting the release layer 14 and the inorganic film may be stuck to the support plate 12 and the substrate 11.

It is to be noted that in the case of using a metal film as the release layer 14, reflection of the laser, electrification onto the film, or the like may be caused depending upon conditions such as a film quality of the release layer 14, a type of a laser light source, and a laser output. For that reason, it is preferable to take a countermeasure thereto by providing an antireflection film or an antistatic film on both or either one of the top and bottom of the release layer 14.

(Compound Having an Infrared Ray Absorbing Structure)

The release layer 14 may also be formed of a compound having an infrared ray absorbing structure. The compound concerned is denatured upon absorption of an infrared ray. As a result of denaturation of the compound, the release layer 14 loses the strength or adhesiveness before receiving the irradiation with an infrared ray. Therefore, by applying a slight external force (for example, lifting up the support plate 12, etc.), the release layer 14 is broken, thereby making it possible to separate the support plate 12 and the substrate 11 from each other with ease.

For example, the structure having infrared ray absorption properties or the compound containing a structure having infrared ray absorption properties may be alkane, alkene (vinyl, trans, cis, vinylidene, trisubstituted, tetrasubstituted, conjugated, cumulene, cyclic), alkyne (monosubstituted, disubstituted), monocyclic aromatic series (benzene, monosubstituted, disubstituted, trisubstituted), alcohols and phenols (free OH, intramolecular hydrogen bond, intermolecular hydrogen bond, secondary saturated, tertiary saturated, secondary unsaturated, tertiary unsaturated), acetal, ketal, aliphatic ether, aromatic ether, vinyl ether, oxirane ring ether, peroxide ether, ketone, dialkylcarbonyl, aromatic carbonyl, enol of 1,3-diketone, o-hydroxyaryl ketone, dialkyl aldehyde, aromatic aldehyde, carboxylic acid (dimer, carboxylate anion), formic acid ester, acetic acid ester, conjugated ester, non-conjugated ester, aromatic ester, lactone (β-, γ-, δ-), aliphatic acid chloride, aromatic acid chloride, acid anhydride (conjugated, non-conjugated, cyclic, non-cyclic), primary amide, secondary amide, lactam, primary amine (aliphatic, aromatic), secondary amine (aliphatic, aromatic), tertiary amine (aliphatic, aromatic), primary amine salt, secondary amine salt, tertiary amine salt, ammonium ion, aliphatic nitrile, aromatic nitrile, carbodiimide, aliphatic isonitrile, aromatic isonitrile, isocyanic acid ester, thiocyanic acid ester, aliphatic isothiocyanic acid ester, aromatic isothiocyanic acid ester, aliphatic nitro compound, aromatic nitro compound, nitroamine, nitrosamine, nitric acid ester, nitrous acid ester, nitroso bond (aliphatic, aromatic, monomer, dimer), sulfur compound such as mercaptan, thiophenol, and thiol acid, thiocarbonyl group, sulfoxide, sulfone, sulfonyl chloride, primary sulfonamide, secondary sulfonamide, sulfuric acid ester, carbon-halogen bond, Si-A¹ bond (A¹ is H, C, O, or halogen), P-A² bond (A² is H, C, or O), or Ti—O bond.

Examples of the above-described structure containing a carbon-halogen bond include —CH₂Cl, —CH₂Br, —CH₂I, —CF₂—, —CF₃, —CH═CF₂, —CF═CF₂, aryl fluoride, and aryl chloride.

Examples of the above-described structure containing an Si-A¹ bond include SiH, SiH₂, SiH₃, Si—CH₃, Si—CH₂—, Si—C₆H₅, SiO aliphatic series, Si—OCH₃, Si—OCH₂CH₃, Si—OC₆H₅, Si—O—Si, Si—OH, SiF, SiF₂, and SiF₃. In particular, as for the structure containing an Si-A¹ bond, it is preferable that a siloxane structure or a silsesquioxane structure is formed.

Examples of the above-described structure containing a P-A² bond include PH, PH₂, P—CH₃, P—CH₂—, P—C₆H₅, A³₃-P—O (A³ is aliphatic series or aromatic series), (A⁴O)₃—P—O (A⁴ is alkyl), P—OCH₃, P—OCH₂CH₃, P—OC₆H₅, P—O—P, P—OH, and P(═O)—OH.

The above-described structure can absorb an infrared ray having a desired wavelength range by selecting the kind thereof. Specifically, the wavelength of the infrared ray which can be absorbed by the above-described structure is, for example, in the range of 1 μm to 20 μm, and more suitably in the range of 2 μm to 15 μm. Furthermore, in the case where the above-described structure is an Si—O bond, an Si—C bond, or a Ti—O bond, the wavelength of the infrared ray which can be absorbed by the above-described structure may be in the range of 9 μm to 11 μm. It is to be noted that a person skilled in the art can easily understand the wavelength of an infrared ray which can be absorbed by each structure. For example, as for the absorption band of each structure, reference can be made to a non-patent literature: “Spectrometric identification of organic compounds (fifth edition)—Simultaneous use of MS, IR, NMR, or UV—” (published in 1992), pages 146 to 151, written by Silverstein, Bassler, and Morrill.

The compound having an infrared ray absorbing structure which is used for the formation of the release layer 14 is not particularly limited so long as the compound has the above-described structure and can be dissolved in a solvent for the purpose of application and solidified to form a solid layer. However, in order to effectively denature the compound in the release layer 14 and facilitate the separation of the support plate 12 from the substrate 11, it is preferable that the absorption of an infrared ray in the release layer 14 is large, namely when an infrared ray is radiated on the release layer 14, a transmittance of the infrared ray is low. Specifically, the transmittance of the infrared ray in the release layer 14 is preferably lower than 90%, and the transmittance of the infrared ray is more preferably lower than 80%.

When the description is made by reference to an example, as the compound having a siloxane structure, for example, a resin that is a copolymer of a repeating unit represented by the following chemical formula (1) and a repeating unit represented by the following chemical formula (2), or a resin that is a copolymer of a repeating unit represented by the following chemical formula (1) and a repeating unit derived from an acrylic compound can be used.

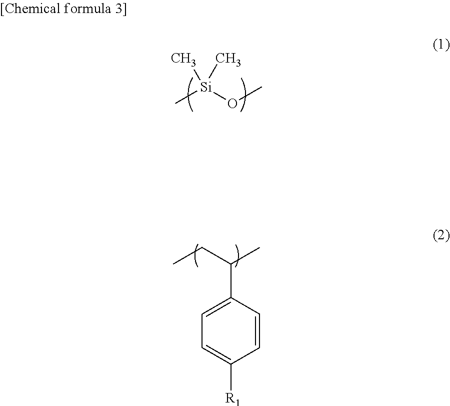

In the foregoing chemical formula (2), R₁ is hydrogen, an alkyl group having not more than 10 carbon atoms, or an alkoxy group having not more than 10 carbon atoms.

Above all, the compound having a siloxane structure is more preferably a tert-butylstyrene (TBST)-dimethylsiloxane copolymer that is a copolymer of the repeating unit represented by the foregoing chemical formula (1) and a repeating unit represented by the following chemical formula (3), and still more preferably a TBST-dimethylsiloxane copolymer containing the repeating unit represented by the foregoing chemical formula (1) and the repeating unit represented by the following chemical formula (3) in a ratio of 1/1.

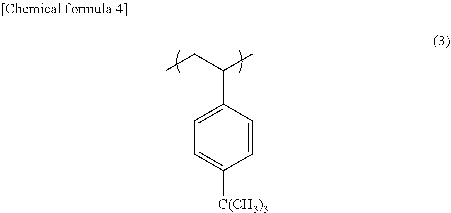

In addition, as for the compound having a silsesquioxane structure, for example, a resin that is a copolymer of a repeating unit represented by the following chemical formula (4) and a repeating unit represented by the following chemical formula (5) can be used.

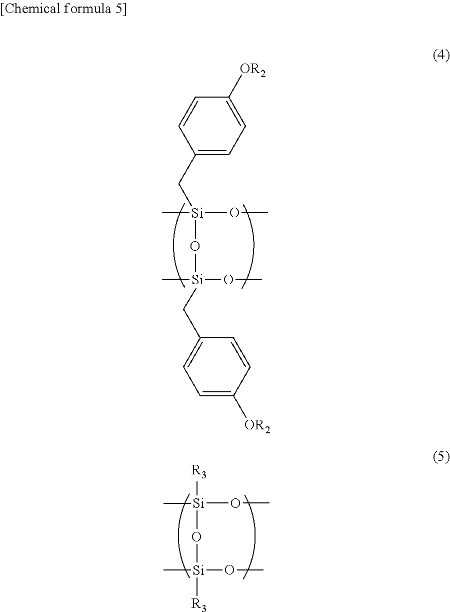

In the foregoing chemical formula (4), R₂ is hydrogen or an alkyl group having 1 or more and not more than 10 carbon atoms; and in the foregoing chemical formula (5), R₃ is an alkyl group having 1 or more and not more than 10 carbon atoms or a phenyl group.

Besides, as the compound having a silsesquioxane structure, respective silsesquioxane resins disclosed in Patent Literature 3: Japanese Patent Application Publication, Tokukai, No. 2007-258663 (Publication Date: Oct. 4, 2007), Patent Literature 4: Japanese Patent Application Publication, Tokukai, No. 2010-120901 (Publication Date: Jun. 3, 2010), Patent Literature 5: Japanese Patent Application Publication, Tokukai, No. 2009-263316 (Publication Date: Nov. 12, 2009), and Patent Literature 6: Japanese Patent Application Publication, Tokukai, No. 2009-263596 (Publication Date: Nov. 12, 2009) can be suitably utilized.

Above all, the compound having a silsesquioxane structure is more preferably a copolymer of a repeating unit represented by the following chemical formula (6) and a repeating unit represented by the following chemical formula (7), and still more preferably a copolymer containing the repeating unit represented by the following chemical formula (6) and the repeating unit represented by the following chemical formula (7) in a ratio of 7/3.

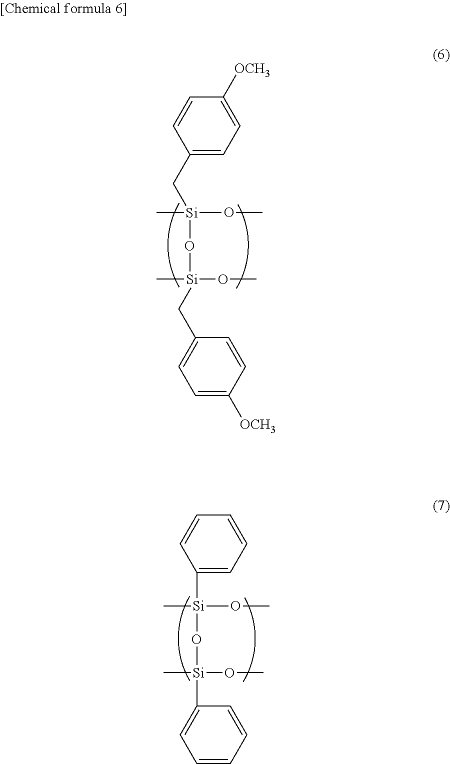

The polymer having a silsesquioxane structure may have any of a random structure, a ladder structure, and a basket structure.

In addition, examples of the compound containing a Ti—O bond include (i) alkoxy titanium such as tetra-i-propoxytitanium, tetra-n-butoxytitanium, tetrakis(2-ethylhexyloxy)titanium, and titanium-i-propoxyoctylene glycolate; (ii) chelate titanium such as di-i-propoxy bis(acetylacetonato)titanium and propanedioxytitanium bis(ethylacetoacetate); (iii) titanium polymers such as i-C₃H₇O—[—Ti(O-i-C₃H₇)₂—O—]ₙ-i-C₃H₇ and n-C₄H₉O—[—Ti(O-n-C₄H₉)₂—O—]ₙ-n-C₄H₉; (iv) titanium acylates such as tri-n-butoxytitanium monostearate, titanium stearate, di-i-propoxytitanium diisostearate, and (2-n-butoxycarbonylbenzoyloxy)tributoxytitanium; and (v) water-soluble titanium compounds such as di-n-butoxy bis(triethanolaminato)titanium.

Above all, the compound containing a Ti—O bond is preferably di-n-butoxy bis(triethanolaminato)titanium (Ti(OC₄H₉)₂[OC₂H₄N(C₂H₄OH)₂]₂).

Though the release layer 14 contains the compound having an infrared ray absorbing structure, the release layer 14 may further contain other component than the above-described compounds. Examples of the component concerned include a filler, a plasticizer, and a component capable of enhancing separation properties of the support plate 12. Such a component is properly selected among conventionally known substances or materials that do not hinder the absorption of infrared ray by the above-described structure and the denaturation of the compound, or promote them.

(Fluorocarbon)

The release layer 14 may also be made of a fluorocarbon. In view of the fact that the release layer 14 is constituted of a fluorocarbon, it is denatured upon absorption of light. As a result, the release layer 14 loses the strength or adhesiveness before receiving the irradiation with light. Therefore, by applying a slight external force (for example, lifting up the support plate 12, etc.), the release layer 14 is broken, thereby making it possible to separate the support plate 12 and the substrate 11 from each other with ease.

In addition, from one viewpoint, the fluorocarbon constituting the release layer 14 may be suitably deposited by a plasma CVD method. It is to be noted that the fluorocarbon includes CₓF_{y} (perfluorocarbon) and CₓH_{y}F_{z} (each of x, y, and z is an integer), and it is not limited thereto; however, the fluorocarbon may be, for example, CHF₃, CH₂F₂, C₂H₂F₂, C₄F₈, C₂F₆, C₅F₈, etc. In addition, if desired, an inert gas such as nitrogen, helium, and argon, a hydrocarbon such as an alkane and an alkene, oxygen, carbon dioxide, or hydrogen may be added to the fluorocarbon which is used for the purpose of constituting the release layer 14. In addition, a mixture of a plurality of these gases may also be used (a mixed gas of a fluorocarbon, hydrogen, and nitrogen, etc.). In addition, the release layer 14 may be constituted of a single kind of a fluorocarbon, or may be constituted of two or more kinds of fluorocarbons.

The fluorocarbon absorbs light having a wavelength of an inherent range depending upon its kind. By irradiating the release layer 14 with light having a wavelength of a range where the fluorocarbon used in the release layer 14 absorbs, the fluorocarbon may be suitably denatured. It is to be noted that an absorbance of light in the release layer 14 is preferably 80% or more.

The light which is radiated on the release layer 14 may be properly used among solid lasers such as a YAG laser, a ruby laser, a glass laser, a YVO₄ laser, an LD laser, and a fiber laser; liquid lasers such as a dye laser; gas lasers such as a CO₂ laser, an excimer laser, an Ar laser, and a He—Ne laser; laser lights such as a semiconductor laser and a free electron laser; and non-laser lights, depending upon the wavelength which can be absorbed by the fluorocarbon. Though the wavelength at which the fluorocarbon may be denatured is not limited thereto, a laser having a wavelength in the range of, for example, not more than 600 nm can be used.

(Infrared Ray Absorbing Substance)

The release layer 14 may also contain an infrared ray absorbing substance. In view of the fact that the release layer 14 is constituted by containing an infrared ray absorbing substance, it is denatured upon absorption of light. As a result, the release layer 14 loses the strength or adhesiveness before receiving the irradiation with light. Therefore, by applying a slight external force (for example, lifting up the support plate 12, etc.), the release layer 14 is broken, thereby making it possible to separate the support plate 12 and the substrate 11 from each other with ease.

The infrared ray absorbing substance may be constituted such that it is denatured upon absorption of an infrared ray, and for example, carbon black, an iron particle, or an aluminum particle can be suitably used. The infrared ray absorbing substance absorbs light having a wavelength of an inherent range depending upon its kind. By irradiating the release layer 14 with light having a wavelength of a range where the infrared ray absorbing substance used in the release layer 14 absorbs, the infrared ray absorbing substance may be suitably denatured.

[Adhesive Layer]

The adhesive layer 13 is configured to adhere and fix the substrate 11 to the support plate 12 and simultaneously cover and protect the surface of the substrate 11. Therefore, at the time of processing or conveyance of the substrate 11, the adhesive layer 13 is required to have adhesiveness and strength for fixing the substrate 11 to the support plate 12 and maintaining a coating on a face of the substrate 11 to be protected. On the other hand, the adhesive layer 13 is required such that when the fixation of the substrate 11 to the support plate 12 becomes unnecessary, it may be easily peeled or removed from the substrate 11.

In consequence, the adhesive layer 13 is constituted of an adhesive which has, in general, firm adhesiveness, the adhesiveness being, however, lowered by some treatment, or which has solubility in a specified solvent. A thickness of the adhesive layer 13 is, for example, more preferably 1 μm to 200 μm, and still more preferably 10 μm to 150 μm. The adhesive layer 13 can be formed by applying an adhesive material as described below onto the substrate 11 by a conventionally known method such as spin application.

As for the adhesive, a variety of adhesives which are known in the field concerned, for example, acrylic adhesives, novolak-based adhesives, naphthoquinone-based adhesives, hydrocarbon-based adhesives, polyimide-based adhesives, etc., can be used as the adhesive constituting the adhesive layer 13 in the present embodiment. A composition of the resin which the adhesive layer 13 contains in the present embodiment is hereunder described.

The resin which the adhesive layer 13 contains only needs to be a resin having adhesiveness, and examples thereof include hydrocarbon resins, acrylic-styrene-based resins, maleimide-based resins, and combinations thereof.

(Hydrocarbon Resin)

The hydrocarbon resin is a resin having a hydrocarbon structure and obtained by polymerizing a monomer composition. Examples of the hydrocarbon resin include a cycloolefin-based polymer (hereinafter sometimes referred to as “resin (A)”) and at least one resin selected from the group consisting of a terpene resin, a rosin-based resin, and a petroleum resin (hereinafter sometimes referred to as “resin (B)”). However, the hydrocarbon resin is not limited thereto.

The resin (A) may also be a resin obtained by polymerizing a monomer component containing a cycloolefin-based monomer. Specifically, examples thereof include a ring-opened (co)polymer of a monomer component containing a cycloolefin-based monomer and a resin obtained by addition (co)polymerizing a monomer component containing a cycloolefin-based monomer.

Examples of the cycloolefin-based monomer contained in the monomer component constituting the resin (A) include bicyclics such as norbornene and norbornadiene; tricyclics such as dicyclopentadiene and dihydroxypentadiene; tetracyclics such as tetracyclododecene; pentacyclics such as cyclopentadiene trimer; heptacyclics such as tetracyclopentadiene; and substituted alkyls (methyl, ethyl, propyl, butyl, etc.), substituted alkenyls (vinyl, etc.), substituted alkylidenes (ethylidene, etc.), or substituted aryls (phenyl, tolyl, naphthyl, etc.) of these polycyclics. Of these, in particular, a norbornene-based monomer selected from the group consisting of norbornene, tetracyclododecene, and a substituted alkyl thereof is preferable.

The monomer component constituting the resin (A) may contain other monomer copolymerizable with the above-described cycloolefin-based monomer. For example, it is preferable that the monomer component constituting the resin (A) contains an alkene monomer. Examples of the alkene monomer include ethylene, propylene, 1-butene, isobutene, 1-hexene, and an α-olefin. The alkene monomer may be linear, or may be branched.

In addition, from the viewpoint of high heat resistance (low thermal decomposition and thermal weight loss properties), it is preferable that a cycloolefin monomer is contained as the monomer component constituting the resin (A). A proportion of the cycloolefin monomer relative to the whole of the monomer component constituting the resin (A) is preferably 5 mol % or more, more preferably 10 mol % or more, and still more preferably 20 mol % or more. In addition, though the proportion of the cycloolefin monomer relative to the whole of the monomer component constituting the resin (A) is not particularly limited, from the viewpoints of solubility and stability with time in a solution, it is preferably not more than 80 mol %, and more preferably not more than 70 mol %.

In addition, a linear or branched alkene monomer may also be contained as the monomer component constituting the resin (A). From the viewpoints of solubility and flexibility, a proportion of the alkene monomer relative to the whole of the monomer component constituting the resin (A) is preferably 10 mol % to 90 mol %, more preferably 20 mol % to 85 mol %, and still more preferably 30 mol % to 80 mol %.

It is to be noted that from the standpoint of suppressing the generation of a gas at a high temperature, the resin (A) is preferably a resin not having a polar group, for example, a resin obtained by polymerizing the monomer component composed of a cycloolefin-based monomer and an alkene monomer.

The polymerization method or polymerization condition or the like at the time of polymerizing the monomer component is not particularly limited and may be properly set up according to the usual way.

Examples of commercially available products which can be used as the resin (A) include “TOPAS” (manufactured by Polyplastics Co., Ltd.), “APEL” (manufactured by Mitsui Chemicals, Inc.), “ZEONOR” and “ZEONEX” (manufactured by Zeon Corporation), and “ARTON” (manufactured by JSR Corporation).

A glass transition temperature (Tg) of the resin (A) is preferably 60° C. or higher, and especially preferably 70° C. or higher. When the glass transition temperature of the resin (A) is 60° C. or higher, it is possible to further suppress softening of the adhesive layer when the adhesive laminate is exposed to a high-temperature environment.

The resin (B) is at least one resin selected from the group consisting of a terpene-based resin, a rosin-based resin, and a petroleum resin. Specifically, examples of the terpene-based resin include a terpene resin, a terpene phenol resin, a denatured terpene resin, a hydrogenated terpene resin, and a hydrogenated terpene phenol resin. Examples of the rosin-based resin include rosin, a rosin ester, hydrogenated rosin, a hydrogenated rosin ester, a polymerized rosin, a polymerized rosin ester, and denatured rosin. Examples of the petroleum resin include an aliphatic or aromatic petroleum resin, a hydrogenated petroleum resin, a denatured petroleum resin, an alicyclic petroleum resin, and a coumarone-indene petroleum resin. Of these, a hydrogenated terpene resin and a hydrogenated petroleum resin are more preferable.

Though a softening temperature of the resin (B) is not particularly limited, it is preferably 80° C. to 160° C. When the softening temperature of the resin (B) is 80° C. or higher, it is possible to suppress softening of the adhesive laminate when it is exposed to a high-temperature environment, thereby preventing deficient adhesion from occurring. On the other hand, when the softening temperature of the resin (B) is not higher than 160° C., the peeling rate becomes satisfactory when the adhesive laminate is peeled.

Though a molecular weight of the resin (B) is not particularly limited, it is preferably 300 to 3,000. When the molecular weight of the resin (B) is 300 or more, the heat resistance becomes sufficient, and the amount of degasification in a high-temperature environment becomes small. On the other hand, when the molecular weight of the resin (B) is not more than 3,000, the peeling rate becomes satisfactory when the adhesive laminate is peeled. It is to be noted that the molecular weight of the resin (B) in the present embodiment means a molecular weight as reduced into polystyrene as measured by gel permeation chromatography (GPC).

It is to be noted that a mixture of the resin (A) and the resin (B) may be used as the resin. By mixing, the heat resistance and the peeling rate become satisfactory. For example, a mixing proportion of the resin (A) and the resin (B) is preferably 80/20 to 55/45 in terms of a mass ratio of (A)/(B) because the peeling rate, the heat resistance in a high-temperature environment, and the flexibility are excellent.

(Block Copolymer)

The block copolymer which may constitute the adhesive layer which is included in the laminate is a polymer in which two or more kinds of block sites having monomer units continuously bound therein are bound and is sometimes referred to as a block copolymer.

It is possible to use a variety of block copolymers as the block copolymer. For example, a styrene-isoprene-styrene block copolymer (SIS), a styrene-butadiene-styrene block copolymer (SBS), a styrene-butadiene-butylene-styrene block copolymer (SBBS), an ethylene-propylene terpolymer (EPT), and hydrogenated materials thereof, a styrene-ethylene-butylene-styrene block copolymer (SEBS), a styrene-ethylene-propylene-styrene block copolymer (styrene-isoprene-styrene block copolymer) (SEPS), a styrene-ethylene-ethylene-propylene-styrene block copolymer (SEEPS), or the like can be used.

To the block copolymer which may constitute the adhesive layer which is included in the laminate, at least one functional group-containing atomic group may be bound. Such a block copolymer can be obtained by, for example, binding at least one functional group-containing atomic group to a known block copolymer using a denaturing agent.

The functional group-containing atomic group is an atomic group containing one or more functional groups. Examples of the functional group which is contained in the functional group-containing atomic group include an amino group, an acid anhydride group (preferably a maleic anhydride group), an imide group, a urethane group, an epoxy group, an imino group, a hydroxyl group, a carboxyl group, a silanol group, and an alkoxysilane group (the alkoxy group thereof preferably has 1 to 6 carbon atoms). The block copolymer is an elastomer and has a functional group capable of bringing about polarity. By containing a block copolymer having at least one functional group-containing atomic group, the flexibility and adhesiveness of the adhesive composition are enhanced.

The block copolymer is preferably a diblock copolymer or a triblock copolymer, and more preferably a triblock copolymer. In addition, a combination of a diblock copolymer and a triblock copolymer may also be used. According to this, it is possible to make a loss factor (tan δ) at 220° C. of the adhesive layer formed using the adhesive composition to be an optimum value of not more than 1.1.

In addition, it is preferable that the block copolymer contains a styrene group, and it is more preferable that the both end terminals of a main chain thereof are a styrene group. This is because by blocking the both end terminals with styrene having high heat stability, higher heat stability is revealed.

The content of the styrene group of the block copolymer is preferably 10% by weight or more and not more than 65% by weight, and more preferably 13% by weight or more and not more than 45% by weight. According to this, it is possible to make a Young's modulus at 23° C. of the adhesive layer formed using the adhesive composition to be an optimum value of 0.1 GPa or more.

Furthermore, a weight average molecular weight of the block copolymer is preferably 50,000 or more and not more than 150,000, and more preferably 60,000 or more and not more than 120,000. According to this, it is possible to make a storage elastic modulus (G′) at 220° C. of the adhesive layer formed using the adhesive composition to be an optimum value of not more than 1×10⁵ Pa.

In addition, the case where the content of the styrene group of the block copolymer is 13% by weight or more and not more than 50% by weight, and the weight average molecular weight of the block copolymer is 50,000 or more and not more than 150,000 is more preferable because the solubility in a hydrocarbon-based solvent is excellent. According to this, when the adhesive layer formed of this adhesive composition is removed, the adhesive layer can be removed easily and rapidly by using a hydrocarbon-based solvent.

Furthermore, the block copolymer is more preferably a hydrogenated material. When the block copolymer is a hydrogenated material, the stability against heat is much more enhanced, and denaturation such as decomposition and polymerization hardly occurs. In addition, the case where the block copolymer is a hydrogenated material is also more preferable from the viewpoints of solubility in a hydrocarbon-based solvent and resistance to a resist solvent.

In addition, it is preferable that the block copolymer contains a unit having a glass transition temperature of not higher than 23° C. When the block copolymer contains a unit having a glass transition temperature of not higher than 23° C., it is possible to make the Young's modulus at 23° C. of the adhesive layer formed using the adhesive composition to be an optimum value of 0.1 GPa or more.

Plural kinds of the block copolymer may be mixed. Namely, the adhesive composition may contain plural kinds of the block copolymer. It is preferable that at least one of plural kinds of the block copolymer contains a styrene group. Furthermore, the case where the content of the styrene group in the at least one of plural kinds of the block copolymer is in the range of 10% by weight or more and not more than 65% by weight, or the case where the weight average molecular weight in the at least one of plural kinds of the block copolymer is in the range of 50,000 or more and not more than 150,000, falls within the scope of the present invention. In addition, in the adhesive composition, in the case of containing plural kinds of the block copolymer, the content of the styrene group may be adjusted so as to fall within the foregoing range as a result of mixing.

(Acrylic-Styrene-Based Resin)

Examples of the acrylic-styrene-based resin include resins obtained by polymerizing, as monomers, styrene or a derivative of styrene and a (meth)acrylic acid ester or the like.

Examples of the (meth)acrylic acid ester include a (meth) acrylic acid alkyl ester composed of a chain structure, a (meth)acrylic acid ester having an aliphatic ring, and a (meth)acrylic acid ester having an aromatic ring. Examples of the (meth)acrylic acid alkyl ester composed of a chain structure include an acrylic long-chain alkyl ester having an alkyl group having 15 to 20 carbon atoms; and an acrylic alkyl ester having an alkyl group having 1 to 14 carbon atoms. Examples of the acrylic long-chain alkyl ester include alkyl esters of acrylic acid or methacrylic acid, in which the alkyl group thereof is an n-pentadecyl group, an n-hexadecyl group, an n-heptadecyl group, an n-octadecyl group, an n-nonadecyl group, an n-eicosyl group, or the like. It is to be noted that the alkyl group concerned may be branched, too.

Examples of the acrylic alkyl ester having an alkyl group having 1 to 14 carbon atoms include a known acrylic alkyl ester which is used for existing acrylic adhesives. Examples thereof include alkyl esters of acrylic acid or methacrylic acid, in which the alkyl group thereof is a methyl group, an ethyl group, a propyl group, a butyl group, a 2-ethylhexyl group, an isooctyl group, an isononyl group, an isodecyl group, a dodecyl group, a lauryl group, a tridecyl group, or the like.

Examples of the (meth)acrylic acid ester having an aliphatic ring include cyclohexyl (meth)acrylate, cyclopentyl (meth)acrylate, 1-adamantyl (meth)acrylate, norbornyl (meth)acrylate, isobornyl (meth)acrylate, tricyclodecanyl (meth)acrylate, tetracyclododecanyl (meth)acrylate, and dicyclopentanyl (meth)acrylate, with isobornyl methacrylate or dicyclopentanyl (meth)acrylate being more preferable.

Though the (meth)acrylic acid ester having an aromatic ring is not particularly limited, examples of the aromatic ring include a phenyl group, a benzyl group, a tolyl group, a xylyl group, a biphenyl group, a naphthyl group, an anthracenyl group, a phenoxymethyl group, and a phenoxyethyl group. In addition, the aromatic ring may have a chain or branched alkyl group having 1 to 5 carbon atoms. Specifically, phenoxyethyl acrylate is preferable.

(Maleimide-Based Resin)

Examples of the maleimide-based resin include resins obtained by polymerizing, as a monomer, a maleimide having an alkyl group, such as N-methylmaleimide, N-ethylmaleimide, N-n-propylmaleimide, N-isopropylmaleimide, N-n-butylmaleimide, N-isobutylmaleimide, N-sec-butylmaleimide, N-tert-butylmaleimide, N-n-pentylmaleimide, N-n-hexylmaleimide, N-n-heptylmaleimide, N-n-octylmaleimide, N-laurylmaleimide, and N-stearylmaleimide; a maleimide having an aliphatic hydrocarbon group, such as N-cyclopropylmaleimide, N-cyclobutylmaleimide, N-cyclopentylmaleimide, N-cyclohexylmaleimide, N-cycloheptylmaleimide, and N-cyclooctylmaleimide; an aromatic maleimide having an aryl group, such as N-phenylmaleimide, N-m-methylphenylmaleimide, N-o-methylphenylmaleimide, and N-p-methylphenylmaleimide; or the like.

For example, a cycloolefin copolymer which is a copolymer of a repeating unit represented by the following chemical formula (8) and a repeating unit represented by the following chemical formula (9) can be used as the resin of the adhesive component.

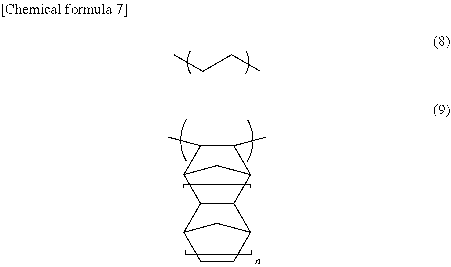

In the foregoing chemical formula (9), n is 0 or an integer of 1 to 3.

As such a cycloolefin copolymer, APL 8008T, APL 8009T, and APL 6013T (all of which are manufactured by Mitsui Chemicals, Inc.), and the like can be used.

It is to be noted that it is preferable to form the adhesive layer 13 using a resin other than a photocurable resin (for example, a UV-curable resin). This is because there may be the case where after peeling or removal of the adhesive layer 13, the photocurable resin remains as a residue in the surroundings of fine irregularities of the substrate 11. In particular, an adhesive capable of being dissolved in a specified solvent is preferable as the material constituting the adhesive layer 13. This is because it is possible to remove the adhesive layer upon being dissolved in the solvent without applying a physical force to the substrate 11. On the occasion of removal of the adhesive layer 13, it is possible to easily remove the adhesive layer 13 even from the substrate 11 whose strength has been lowered, without damaging or deforming the substrate 11.

Examples of a diluent solvent when the above-described release layer or adhesive layer is formed include linear hydrocarbons or branched hydrocarbons having 4 to 15 carbon atoms such as hexane, heptane, octane, nonane, methyloctane, decane, undecane, dodecane, and tridecane; terpene-based solvents such as p-menthane, o-menthane, m-menthane, diphenylmenthane, 1,4-terpin, 1,8-terpin, bornane, norbornane, pinane, thujane, carane, longifolene, geraniol, nerol, linalool, citral, citronellol, menthol, isomenthol, neomenthol, α-terpineol, β-terpineol, γ-terpineol, terpinen-i-ol, terpinen-4-ol, dihydroterpinyl acetate, 1,4-cineole, 1,8-cineole, borneol, carvone, ionone, thujone, camphor, d-limonene, 1-limonene, and dipentene; lactones such as γ-butyrolactone; ketones such as acetone, methyl ethyl ketone, cyclohexanone (CH), methyl-n-pentyl ketone, methyl isopentyl ketone, and 2-heptanone; polyhydric alcohols such as ethylene glycol, diethylene glycol, propylene glycol, and dipropylene glycol; derivatives of polyhydric alcohols, such as compounds having an ester bond, for example, ethylene glycol monoacetate, diethylene glycol monoacetate, propylene glycol monoacetate, or dipropylene glycol monoacetate, and compounds having an ether bond, for example, monoalkyl ethers or monophenyl ethers, e.g., monomethyl ethers, monoethyl ethers, monopropyl ethers, or monobutyl ethers of the above-described polyhydric alcohols or the above-described compounds having an ester bond (of these, propylene glycol monomethyl ether acetate (PGMEA) or propylene glycol monomethyl ether (PGME) is preferable); cyclic ethers such as dioxane, or esters such as methyl lactate, ethyl lactate (EL), methyl acetate, ethyl acetate, butyl acetate, methoxybutyl acetate, methyl pyruvate, ethyl pyruvate, methyl methoxypropionate, and ethyl ethoxypropionate; aromatic organic solvents such as anisole, ethyl benzyl ether, cresyl methyl ether, diphenyl ether, dibenzyl ether, phenetole, and butyl phenyl ether; and condensed polycyclic hydrocarbons.

The condensed polycyclic hydrocarbon is a condensed ring hydrocarbon formed when only one side of each of two or more monocycles is provided. It is preferable to use a hydrocarbon in which two monocycles are condensed.

Examples of such a hydrocarbon include a combination of a 5-membered ring and a 6-membered ring; and a combination of two 6-membered rings. Examples of the hydrocarbon composed of a combination of a 5-membered ring and a 6-membered ring include indene, pentalene, indane, and tetrahydroindene. Examples of the hydrocarbon composed of a combination of two 6-membered rings include naphthalene, tetrahydronaphthalene (tetralin), and decahydronaphthalene (decalin).

[Protective Layer]

The protective layer 15 is a layer for covering a face that is a surface of the release layer 14 and which is not adhered to the support plate 12 and not superimposed at least on the adhesive layer 13. For example, the protective layer 15 is able to protect the release layer 14 such that it is not denatured by a chemical treatment at a high temperature for a long time such as a resist stripping treatment (resist stripping step), or a heat treatment step at a high temperature (for example, 260° C.), which is subsequently conducted.

The face of the release layer 14 which is covered by the protective layer 15 is only necessary to include a face that is a surface of the release layer 14 and which is not adhered to the support plate 12 and not superimposed at least on the adhesive layer 13.

Namely, in the present embodiment, the protective layer 15 also covers a face that is a surface of the release layer 14 and which is not adhered to the support plate 12 but superimposed on the adhesive layer 13. However, the protective layer which is included in the laminate is not limited to such an embodiment, and the protective layer may cover only a face that is a surface of the release layer and which is not adhered to the support and not superimposed on the adhesive layer. In any of these configurations, since the protective layer covers a face that is at least a surface of the release layer and which is not adhered to the support (support plate) and not superimposed at least on the adhesive layer, the protective layer is able to protect the release layer such that it is not denatured by a chemical treatment at a high temperature for a long time such as a resist stripping treatment.

A material that forms the protective layer 15 can be properly selected according to the treatment to be conducted on the laminate 10. Namely, a material having resistance to a chemical which is used in the treatment concerned or an environment at which the treatment concerned is conducted may be properly selected. For example, so long as the laminate 10 is provided for the resist stripping treatment at a high temperature for a long time, a material having resistance to a stripper which is used in the step concerned may be selected.

As a specific example of the material that forms the protective layer 15, for example, an adhesive is exemplified. This is because the adhesiveness to the adhesive layer 13 can be enhanced.

In the case where the protective layer 15 is constituted of an adhesive, the adhesive concerned may be an adhesive having the same composition as that in the adhesive constituting the adhesive layer 13. As described above, an adhesive having chemical resistance to a stripper or the like is selected as the adhesive constituting the adhesive layer 13, and therefore, when the protective layer 15 is formed of such an adhesive, the release layer 14 can be protected satisfactorily.

In addition, the adhesive constituting the protective layer 15 may also be an adhesive having a composition different from that in the adhesive constituting the adhesive layer 13. However, even among such adhesives, an adhesive which may be a candidate for the adhesive constituting the adhesive layer 13 is more preferable. As described above, the adhesive constituting the adhesive layer 13 may be selected among adhesives having chemical resistance to a stripper or the like, and therefore, when the protective layer 15 is formed of an adhesive which may be a candidate for such an adhesive, the release layer 14 can be protected satisfactorily.

Specifically, examples of the material constituting the protective layer 15 include a block copolymer and a cycloolefin-based polymer. These materials may be used solely, or a mixture of plural kinds thereof may also be used. The explanation of the block copolymer and the cycloolefin-based polymer conforms to the explanation regarding each component made in the adhesive layer 13 as described above.

It is preferable that a thickness of the film of the protective layer 15 is, for example, 1 μm to 10 μm. When the thickness of the film of the protective layer 15 is 1 μm or more, the protective layer 15 is tolerable satisfactorily to a variety of chemical treatments at a high temperature for a long time. When the thickness of the film of the protective layer 15 is not more than 10 μm, the substrate 11 can be separated satisfactorily in a step of separating the substrate 11 from the laminate.

<Formation Method 1 of Laminate>

Next, the formation method of the laminate 10 is described by reference to FIGS. 1(a) to 1(f). FIGS. 1(a) to 1(f) are each a view illustrating a method for forming a laminate in the case of removing a portion of a protective layer, which is exposed at the time of forming the laminate, before an adhesion step.

First of all, as illustrated in FIGS. 1(a) and 1(b), the release layer 14 is formed on the support plate 12. Examples of a method for forming the release layer 14 include the above-described methods such as accumulation by a chemical vapor deposition (CVD) method.

Subsequently, as illustrated in FIG. 1(c), the protective layer 15 is formed on the release layer 14 (protective layer forming step). In the protective layer forming step, the protective layer 15 for covering a face that is a surface of the release layer 14 and which is not adhered to the support plate 12 is formed.

Furthermore, as illustrated in FIG. 1(d), in the protective layer 15 formed on the release layer 14, the protective layer 15 formed on a curved surface of the support plate 12 (a portion of the protective layer 15, which is exposed at the time of forming the laminate 10) is removed (protective layer removal step).

Examples of a method for removing the protective layer 15 include a method for dissolving the protective layer 15 formed on the curved surface of the support plate 12 with a solvent and removing it; a method for physically cutting the protective layer 15 formed on the curved surface of the support plate 12 using a cutter or a blade, or the like and removing it; and a method for removing the protective layer 15 formed on the curved surface of the support plate 12 by means of ashing under atmospheric pressure. Of these, from the viewpoints of strength and practicality, a method for removing the protective layer 15 formed on the curved surface of the support plate 12 with a solvent is preferable.

In the method for removing the protective layer 15 with a solvent, the solvent which is used is not particularly limited so long as it may dissolve the protective layer 15 therein, and a person skilled in the art can properly select the solvent depending upon the composition of the protective layer 15. For example, in the case where the protective layer 15 is formed using a hydrocarbon-based adhesive, a terpene-based solvent such as p-menthane and d-limonene can be used as the solvent; and in the case where the protective layer 15 is formed using an acrylic or maleimide-based adhesive, propylene glycol monomethyl ether acetate, cyclohexanone, 2-heptanone, ethyl acetate, methyl ethyl ketone, or the like can be used as the solvent.

Examples of a method for feeding a solvent into the protective layer 15 formed on the curved surface of the support plate 12 include a method for feeding a solvent into the protective layer 15 by means of jetting of the solvent; and a method for dipping the substrate 11 stuck to the support plate 12 via the protective layer in a solvent.

As the method for feeding a solvent into the protective layer 15 formed on the curved surface of the support plate 12 by means of jetting of the solvent, in order to uniformly feed the solvent into the protective layer 15 formed on the curved surface, a method for feeding the solvent into the protective layer 15 formed on the curved surface while rotating the support plate 12 is preferable. Examples of the method for feeding the solvent while rotating the support plate 12 include a method in which a nozzle from which the solvent is jetted is disposed just above a central portion of the support plate 12, and the support plate 12 is rotated at a high speed using a spinner after or while dropping the solvent at a central position of the support plate 12. According to this, the solvent can be uniformly fed into the protective layer 15 formed on the curved surface of the support plate 12 by a centrifugal force. In addition, as another method, there is exemplified a method in which a nozzle from which the solvent is jetted is disposed just above the right outside of the periphery of the support plate 12, and the support plate 12 is rotated using a spinner while dropping the solvent on the right outside of the periphery of the support plate 12. According to this, the solvent can be fed into the right outside of the entire periphery of the support plate 12. Even according to this method, the solvent can also be uniformly fed into the protective layer 15 of any portion exposed from the support plate 12. It is to be noted that in the case where a nozzle from which the solvent is jetted is disposed just above the right outside of the periphery of the support plate 12, the number of nozzles to be disposed is not limited, and it may be 1 or more.

In the above-described method accompanied with the rotation of the substrate 11 and the jetting of the solvent, a rotation speed of the substrate 11, a flow rate of the solvent when the solvent is fed from the nozzle, and a feed time of the solvent may be different according to a composition of the adhesive forming the protective layer 15, a thickness of the protective layer 15, a size of the protective layer 15 of the exposed portion (distance from the periphery of the substrate 11 in the exposed portion), a kind of the solvent used, and a degree of the removal. However, a person skilled in the art is able to examine and determine optimum conditions thereof without difficulty.

In the case of a method for feeding the solvent into the protective layer 15 formed on the curved surface of the support plate 12 for the purpose of dissolving the protective layer 15 with a solvent, it is preferable that after removing the protective layer 15 of the portion formed on the curved surface, the substrate 11 stuck to the support plate 12 is dried. By going through the drying step, the unnecessary solvent and the solvent which has penetrated into the protective layer that is not a portion subjective to the removal can be removed.

Examples of the drying method include drying by shaking by rotating the substrate 11 using a spinner or the like; drying by air blowing by means of spraying of an N₂ gas or the like; drying by baking; and drying by means of pressure reduction. It is to be noted that as for these drying methods, it is possible to adopt any of a method adopting any one method solely and a method of achieving drying by adopting a combination of arbitrary two or more methods.

Subsequently, as illustrated in FIG. 1(e), the release layer 14 may be removed by feeding the solvent into the release layer 14 formed on the curved surface of the support plate 12. At that time, the solvent which is used for removing the release layer 14 formed on the curved surface of the support plate 12 with a solvent is not particularly limited so long as it may dissolve the release layer 14 therein, and a person skilled in the art can properly select the solvent depending upon the composition of the release layer 14. As for the method for feeding the solvent into the release layer 14 formed on the curved surface of the support plate 12, the same method as the method for feeding the solvent into the protective layer 15 as described above can be adopted.

Subsequently, as illustrated in FIG. 1(f), the adhesive layer 13 is formed on at least either one of the protective layer 15 and the substrate 11, and the protective layer 15 and the substrate 11 are stuck to each other via the adhesive layer 13, thereby manufacturing the laminate 10 (adhesion step). At that time, since the protective layer 15 and the release layer 14 formed on the curved surface of the support plate 12 have already been removed, at the time of forming the laminate 10, the protective layer 15 and the release layer 14 are not exposed. In consequence, FIG. 1(d) illustrates that in the protective layer 15, a portion which is exposed at the time of forming the laminate 10 is removed before the adhesion step; and FIG. 1(e) illustrates that in the release layer 14, a portion which is exposed at the time of forming the laminate 10 is removed before the adhesion step.

After the adhesion step, the substrate 11 is subjected to at least one of a heat treatment and a vacuum treatment (processing step). The processing step is a step of subjecting the substrate 11 stuck to the support plate 12 via the adhesive layer 13 to processing accompanied with at least one of a heat treatment and a vacuum treatment in order to achieve back side processing for forming a through electrode on the substrate 11. Here, the heat treatment intends to conduct heating at 100° C. or higher. In addition, the vacuum treatment intends to conduct drying under reduced pressure. All of these treatments promote foaming and denaturation in the adhesive layer 13.

Examples of the processing accompanied with a heat treatment include a lithography step, a cleaning step, and a reflow step.

Examples of the processing accompanied with a vacuum treatment include vacuum plasma treatments such as plasma chemical vapor deposition (plasma CVD) and etching and ashing.

In the light of the above, even when a CVD film is formed on the laminate by a processing step, the protective layer 15 is not exposed. For that reason, even when the CVD film concerned and the protective layer 15 come into contact with each other, the peeling of the protective layer 15 can be suppressed. Furthermore, as illustrated in FIG. 1(e), if in the release layer 14, the portion which is exposed at the time of forming the laminate 10 is removed before the adhesion step, even when the CVD film is formed by a heat treatment or a vacuum treatment, it is possible to prevent peeling of the release layer 14 in the exposed portion from occurring.

It is to be noted that in this specification, the terms “in the protective layer (or release layer), the portion which is exposed at the time of forming the laminate is removed” include not only the case where each of the exposed portions is completely removed but the case where each of the exposed portions is removed to an extent that after the heat treatment or vacuum treatment, it is not peeled off.

<Formation Method 2 of Laminate>

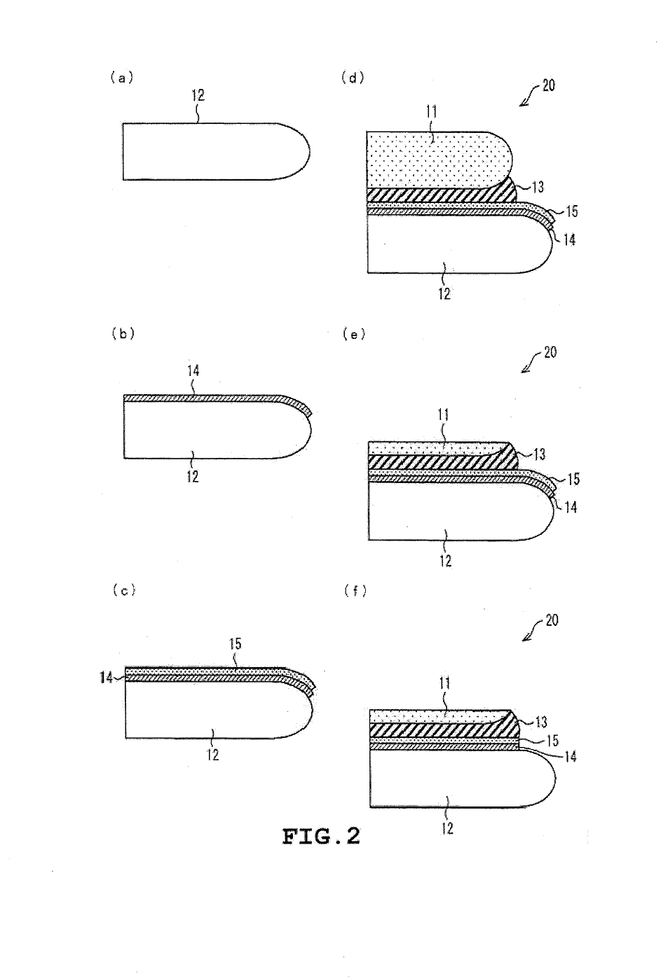

Next, the formation method of a laminate 20 is described by reference to FIGS. 2(a) to 2(f). FIGS. 2(a) to 2(f) are each a view illustrating a method for forming a laminate in the case of removing a portion of a protective layer, which is exposed at the time of forming the laminate, after an adhesion step. It is to be noted that in the above-described formation method 1 of laminate, the protective layer removal step is conducted before the adhesion step, whereas in the present formation method, the protective layer removal step is conducted after the adhesion step. In addition, as for the steps which are common to those in the formation method of a laminate as described above, explanations thereof are omitted.

First of all, as illustrated in FIGS. 2(a) to 2(c), the release layer 14 is formed on the support plate 12, and thereafter, the protective layer 15 is formed on the release layer 14.

Subsequently, as illustrated in FIG. 2(d), the adhesive layer 13 is formed on at least either one of the protective layer 15 and the substrate 11, and the protective layer 15 and the substrate 11 are stuck to each other via the adhesive layer 13, thereby manufacturing the laminate 20 (adhesion step).

As illustrated in FIG. 2(e), a face of the substrate 11 opposite to the face on which the adhesive layer 13 is formed is ground and thinned. Specifically, for example, the substrate 11 may be processed into a prescribed thickness using a grinder.

Then, as illustrate in FIG. 2(f), in the protective layer 15 formed on the release layer 14, the protective layer 15 formed on the curved surface is removed (protective layer removal step). At that time, as illustrated in FIG. 2(f), the release layer 14 may be removed together with the protective layer 15.

In the case where after the adhesion step of sticking the substrate 11 and the support plate 12 to each other, the protective layer removal step is conducted, in the protective layer removal step, it is preferable to remove the protective layer 15 by a solvent treatment or a plasma treatment. As the solvent treatment, the same treatment as that described above may be conducted. As the plasma treatment, an O₂ plasma treatment may be conducted.

After the protective layer removal step, the substrate 11 is subjected to at least one of a heat treatment and a vacuum treatment (processing step).

In the light of the above, even when a CVD film is formed on the laminate by the processing step, the protective layer 15 is not exposed. For that reason, even when the CVD film concerned and the protective layer 15 come into contact with each other, the peeling of the protective layer 15 can be suppressed. Furthermore, as illustrated in FIG. 2(f), if in the release layer 14, the portion which is exposed at the time of forming the laminate 20 is removed before the processing step, even when the CVD film is formed by a heat treatment or a vacuum treatment, it is possible to prevent peeling of the release layer 14 in the exposed portion from occurring.

In the case of removing the protective layer 15 by a plasma treatment in the protective layer removal step, it is preferable to remove the portion of the release layer 14, which is exposed at the time of forming the laminate 20, together with the protective layer 15. According to this, even when after the protective layer removal step, the CVD film is formed by a heat treatment or a vacuum treatment, it is also possible to suppress peeling of the release layer 14.

As a modification example of the present embodiment, there may also be adopted a method in which the portion of the protective layer, which is exposed at the time of forming the laminate, is removed by a solvent treatment, and the portion of the release layer, which is exposed at the time of forming the laminate, is removed by a plasma treatment.

[Formation Method of Laminate]

The method for forming a laminate according to the present invention also includes the case where the protective layer is not formed. Namely, the method for forming a laminate according to the present invention is concerned with a method for forming a laminate comprising laminating a substrate, an adhesive layer, a release layer which is denatured upon absorption of light, and a support supporting the substrate in this order to form a laminate, the method including a release layer removal step of removing a portion of the release layer, which is exposed at the time of forming the laminate, by a plasma treatment.

According to this, when the portion of the release layer, which is exposed at the time of forming the laminate, is subjected to a plasma treatment, the release layer of the exposed portion can be removed. For that reason, even when after the release layer removal step, the CVD film is formed by a heat treatment or a vacuum treatment, it is possible to suppress peeling of the release layer.

The present invention is not limited to the respective embodiments as described above, and it is possible to make various modifications within the scope of the claims. An embodiment derived from a proper combination of technical means disclosed in different embodiments is also included in the technical scope of the present invention.

### EXAMPLES

### Example 1

### Formation of Laminate

(Process)

A fluorocarbon film (thickness: 1 μm) that is a release layer was formed on a support (12-inch glass substrate, thickness: 700 μm) under conditions of a flow rate of 400 sccm, a pressure of 700 mTorr, a high-frequency electric power of 2,500 W, and a deposition temperature of 240° C. by a CVD method using C₄F₈ as a reaction gas, and TZNR-A3007t (manufactured by Tokyo Ohka Kogyo Co., Ltd.) that is an adhesive composition was applied thereonto, followed by baking at 220° C. for 3 minutes, thereby forming a protective layer having a film thickness of 1.5 μm (protective layer forming step). The above-described adhesive composition containing 280 parts by weight of a prime solvent was spin-applied on a 12-inch silicon wafer and heated at 100° C., 160° C. and 200° C. for 3 minutes each, to form an adhesive layer (film thickness: 50 μm), which was then stuck to a glass support in vacuo under conditions of 220° C. and 4,000 kg for 3 minutes, thereby forming a laminate (adhesion step).

### Removal of Protective Layer with Solvent

The protective layer of a portion exposed from the wafer which had been stuck to the support plate via the protective layer was removed using p-menthane. First of all, the wafer was rotated at 1,500 rpm for 10 minutes while feeding the solvent at a flow rate of 20 mL/min from a nozzle for solvent jetting as disposed just above the right outside of the periphery of the wafer. Subsequently, the feed of the solvent was stopped, and the wafer was dried. The drying was carried out by baking at 100° C., 160° C. and 220° C. in this order for 6 minutes each and meanwhile rotating the wafer. Thereafter, the wafer was transferred onto a cooling plate and pinned up, followed by cooling step by step for 3 minutes. According to this, only the protective layer of the portion exposed from the wafer could be removed.

### Removal of Protective Layer by Plasma Treatment

The release layer of a portion exposed from the wafer which had been stuck to the support plate via the adhesive layer was removed by a plasma treatment. The plasma treatment was conducted using an interdigitated array electrode or an ICP electrode under the following conditions.

The plasma treatment in the case of using an interdigitated array electrode was conducted under conditions of a power of 1,200 W, a pressure of 0.5 Torr, a gas flow rate of 1,200 sccm (O₂), a stage temperature of 90° C., and a treatment time by holding by pinning up of 6 minutes. The plasma treatment in the case of using an ICP electrode was conducted under conditions of a power of 600 W, a pressure of 130 Pa, a gas flow rate of 3,800 sccm (O₂) and 200 sccm (N₂+H₂), a stage temperature of 240° C., and a treatment time by holding by pinning up of 90 seconds.

A portion of the protective layer, which was exposed at the time of forming the laminate, could be removed by each of the plasma treatments using an interdigitated array electrode or an ICP electrode under the above-described treatment conditions. Furthermore, a portion of the release layer, which was exposed at the time of forming the laminate, could be removed together with the protective layer.

### Example 2

### Formation of Laminate

A laminate was formed under the same conditions as those in Example 1. The laminate formed in this Example is different from the laminate formed in Example 1 at the point that the protective layer is not formed.

### Removal of Release Layer by Plasma Treatment

Subsequently, the release layer of a portion exposed from the wafer which had been stuck to the support plate via the adhesive layer was removed by a plasma treatment. The plasma treatment was conducted using an interdigitated array electrode or an ICP electrode under the following conditions.

The plasma treatment in the case of using an interdigitated array electrode was conducted under conditions of a power of 1,200 W, a pressure of 0.5 Torr, a gas flow rate of 1,200 sccm (O₂), a stage temperature of 90° C., and a treatment time by holding by pinning up of 3 minutes. The plasma treatment in the case of using an ICP electrode was conducted under conditions of a power of 600 W, a pressure of 130 Pa, a gas flow rate of 3,800 sccm (O₂) and 200 sccm (N₂+H₂), a stage temperature of 240° C., and a treatment time by holding by pinning up of 45 seconds.

A portion of the release layer, which was exposed at the time of forming the laminate, could be removed by each of the plasma treatments using an interdigitated array electrode or an ICP electrode under the above-described treatment conditions.

### INDUSTRIAL APPLICABILITY

The method for forming a laminate according to the present invention can be, for example, suitably utilized in a manufacturing step of a microfabricated semiconductor device.

### EXPLANATIONS OF NUMERALS OR LETTERS

10, 20, 30: Laminate
11, 31: Substrate
12, 32: Support plate (support)
13, 33: Adhesive layer
14, 34: Release layer
15, 35: Protective layer
36: CVD film
37: Peeled material
   While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method for forming a laminate comprising laminating a substrate, an adhesive layer, a release layer which is denatured upon absorption of light, and a support supporting the substrate in this order to form a laminate, the method including:
a protective layer forming step of forming a protective layer for covering a face that is a surface of the release layer and which is not adhered to the support and not superimposed at least on the adhesive layer; and
a protective layer removal step of removing a portion of the protective layer, which is exposed at the time of forming the laminate.

2. The method according to claim 1, wherein the protective layer removal step is conducted before an adhesion step of sticking the substrate and the support to each other.

3. The method according to claim 2, wherein in the protective layer removal step, the protective layer is removed by a solvent treatment.

4. The method according to claim 1, further including an adhesion step of sticking the substrate and the support to each other; and a processing step after the adhesion step, of subjecting the substrate to at least one of a heat treatment and a vacuum treatment,
Wherein the protective layer removal step is conducted after the adhesion step and before the processing step.

5. The method according to claim 4, wherein in the protective layer removal step, the protective layer is removed by a solvent treatment or a plasma treatment.

6. The method according to claim 5, wherein a portion of the release layer, which is exposed at the time of forming the laminate, is removed together with the protective layer by the plasma treatment.

7. A method for forming a laminate comprising laminating a substrate, an adhesive layer, a release layer which is denatured upon absorption of light, and a support supporting the substrate in this order to form a laminate, the method including:
a release layer removal step of removing a portion of the release layer, which is exposed at the time of forming the laminate, by a plasma treatment.

8. The method according to claim 1, further including after the protective layer removal step, the substrate stuck to the support is dried.
